(19) United States
(12) Patent Application Publication
(10) Pub. No.: US 2026/0090405 A1
(43) Pub. Date: Mar. 26, 2026

(54) LEAD FRAME, PACKAGE STRUCTURE AND METHOD FOR FORMING THE SAME

(71) Applicant: JCET Shanghai Automotive Co., LTD., Shanghai (CN)

(72) Inventors: Hyeonggug JIN, Shanghai (CN); Tailong LI, Shanghai (CN); Junfeng ZHANG, Shanghai (CN); Gang JUNG, Shanghai (CN)

(73) Assignee: JCET Shanghai Automotive Co., LTD., Shanghai (CN)

(21) Appl. No.: 19/333,115

(22) Filed: Sep. 18, 2025

(30) Foreign Application Priority Data
Sep. 20, 2024 (CN) 202411316379.7

(51) Int. Cl. H01L 23/495; H01L 21/48; H01L 21/56; H01L 23/00; H01L 23/31

(52) U.S. Cl. CPC H10W 70/435; H10W 70/04; H10W 70/429; H10W 74/01; H10W 74/114; H10W 90/756

(57) ABSTRACT

A lead frame includes a base island; a plurality of leads located around the base island, the adjacent leads having between them a gap, each of the leads comprising an inner lead close to the base island and an outer lead far away from the base island, the inner lead and the outer lead being connected by a connection part; a UV tape covering at least one of a back surface or a front surface of the connection part of each of the leads and filling the gaps between the connection parts of the adjacent leads, the UV tape being configured to prevent molding layer material from overflowing in the direction of the outer leads through the gaps between the adjacent leads during subsequent formation of a molding layer covering the base island and the inner leads, and the UV tape being peeled off after irradiation by a UV light after forming the molding layer.

### CROSS-REFERENCE TO RELATED APPLICATIONS

This application claims the benefit of priority to Chinese Application No. 202411316379.7, filed Sep. 20, 2024, which is incorporated herein by reference in its entirety.

### TECHNICAL FIELD

The present application relates to the field of semiconductor package, and particularly relates to a lead frame, a package structure, and a method for forming the same.

### BACKGROUND

A lead frame, as a part of a semiconductor package, is used in a semiconductor package to support a packaged semiconductor chip and to connect the packaged semiconductor chip with an external device.

### SUMMARY

An embodiment of the present application provides a lead frame, including: a base island; a plurality of leads located around the base island, the adjacent leads having between them a gap, each of the leads comprising an inner lead close to the base island and an outer lead far away from the base island, the inner lead and the outer lead being connected by a connection part; and an ultraviolet (UV) tape covering a back surface and/or a front surface of the connection part of each of the leads and filling the gaps between the connection parts of the adjacent leads, the UV tape being configured to prevent molding layer material from overflowing in the direction of the outer leads through the gaps between the adjacent leads during subsequent formation of a molding layer covering the base island and the inner leads.

In an optional embodiment, the UV tape is retained after formation of the molding layer, or the UV tape is removed after formation of the molding layer by irradiation with UV light; the UV tape comprises a base film and an adhesive film located on the surface of the base film, the adhesive film losing or diminishing its adhesiveness under the irradiation of UV light; the adhesive film being filled in the gaps between the connection parts of the adjacent leads.

In an optional embodiment, the UV tape fully fills the gaps between the connection parts of the adjacent leads.

In an optional embodiment, the lead frame comprises a plurality of lead frame units arranged in rows and columns, each lead frame unit comprising a base island and a plurality of discrete leads located around the base island.

In an optional embodiment, adjacent lead frame units have between them a tie bar, the end of the outer lead in each lead frame unit far away from the connection part being connected with the tie bar, and the base island being connected with the tie bar by means of a dam bar.

In an optional embodiment, a plurality of discrete leads being located around the base island comprises: the plurality of discrete leads being located around the base island, or the plurality of discrete leads being located on two sides of the base island.

Another embodiment of the present application also provides a package structure, including: a lead frame, the lead frame comprising a base island and a plurality of leads located around the base island, the adjacent leads having between them a gap, each of the leads comprising an inner lead close to the base island and an outer lead far away from the base island, the inner lead and the outer lead being connected by a connection part; a semiconductor chip mounted on the front surface of the base island, the semiconductor chip being electrically connected with the inner leads by means of metal wires; a molding layer covering the semiconductor chip, the base island and the inner leads, the molding layer exposing the outer leads; a UV tape covering a back surface and/or a front surface of the connection part of each of the leads and filling the gap between the connection parts of the adjacent leads; and a molding layer covering the semiconductor chip, the base island and the inner leads, the molding layer exposing the outer leads and the UV tape.

In an optional embodiment, a plurality of the leads are located around the base island or a plurality of the leads are located on two sides of the base island.

Yet another embodiment of the present application also provides a method for forming a package structure, including: providing a lead frame, the lead frame comprising a base island and a plurality of leads located around the base island, the adjacent leads having between them a gap, each of the leads comprising an inner lead close to the base island and an outer lead far away from the base island and connected with the inner lead, the inner lead and the outer lead being connected by a connection part; forming a UV tape which covers a back surface and/or a front surface of the connection part of each of the leads and which fills the gap between the connection parts of the adjacent leads; mounting a semiconductor chip on the front surface of the base island; forming a metal wire electrically connecting the semiconductor chip with the inner leads; and forming a molding layer that covers the semiconductor chip, the base island and the inner leads, the molding layer exposing the outer leads and the UV tape, the UV tape being configured to prevent molding layer material from overflowing in the direction of the outer leads through the gaps between the adjacent leads during subsequent formation of a molding layer covering the semiconductor chip, the base island and the inner leads.

In an optional embodiment, the UV tape is retained after forming the molding layer, or the UV tape is removed by UV light irradiation after forming the molding layer.

In an optional embodiment, the base island and leads both comprise opposed front surface and back surface, and the semiconductor chip comprises opposed active surface and back surface, the active surface having a plurality of discrete pads, the semiconductor chip is mounted with its back surface downwards on the front surface of the base island, and the pads on the active surface of the semiconductor chip being electrically connected with the corresponding inner leads.

In an optional embodiment, when forming the molding layer, the front surface and back surface of the connection part are pressed together between the upper and lower molds.

### BRIEF DESCRIPTION OF THE DRAWINGS

FIG. 1 is a top view structural schematic diagram of the existing lead frame; and FIGS. 2-8 are structural schematic diagrams of the formation process of the package structure in some embodiments of the present application.

### DETAILED DESCRIPTION OF EMBODIMENTS

Specific embodiments of the present application are described in detail below in conjunction with the accompanying drawings. When detailing the embodiments of the present application, the schematic drawings will not be partially enlarged in accordance with the general proportion for the convenience of illustration, and the schematic drawings are only examples, which shall not limit the scope of protection of the present application herein. In addition, the three-dimensional spatial dimensions of length, width, and depth should be included in the actual production.

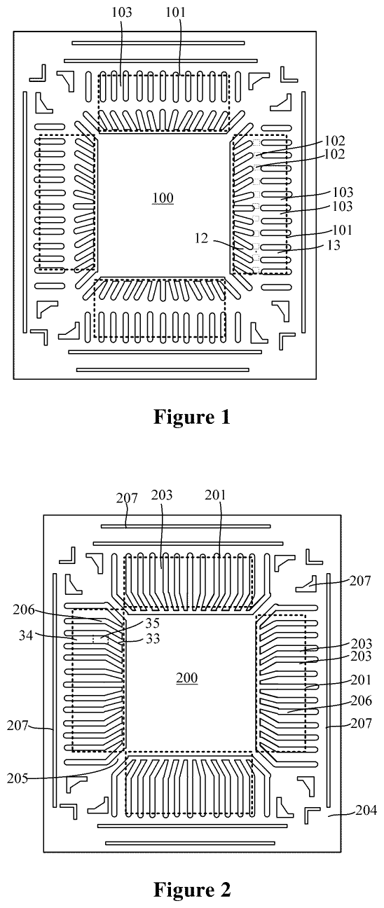

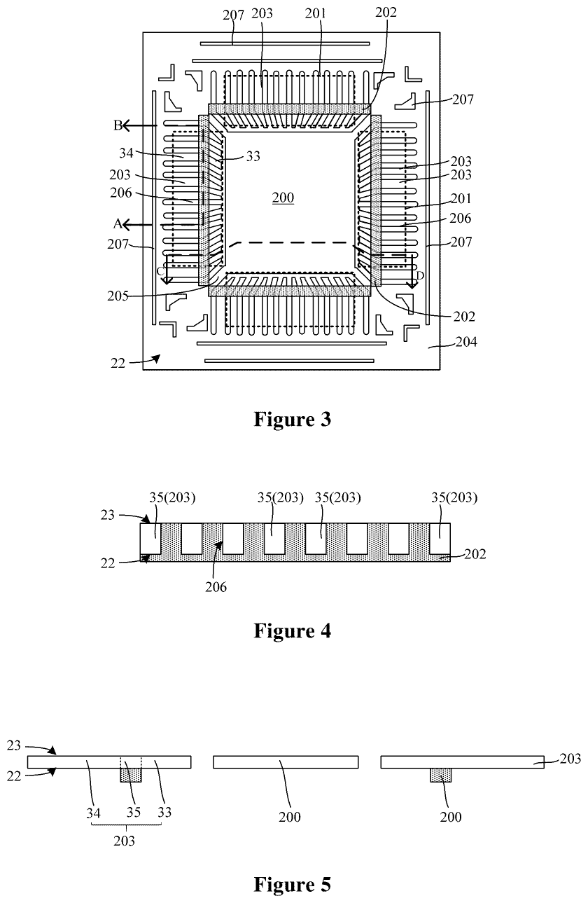

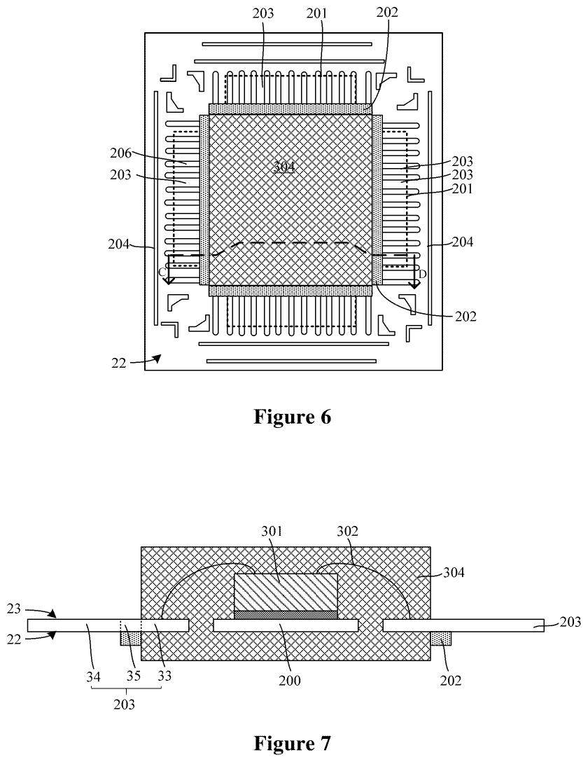

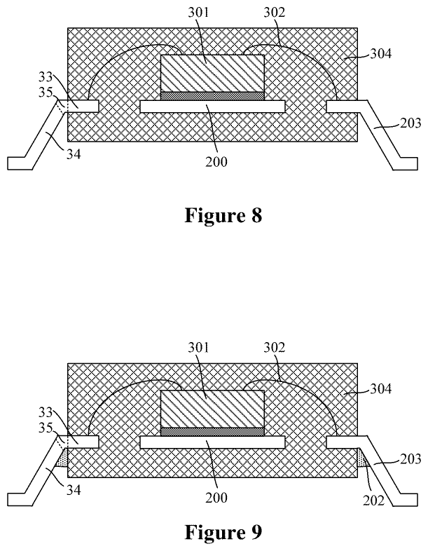

A lead frame is provided, referring to FIG. 1, the lead frame including a base island 100 and a lead area 101 located around the base island 100, the lead area 101 having in it a plurality of leads 103, each of the leads 103 including an inner lead 12 close to the base island 100 and an outer lead 13 far away from the base island 100 and connected with the inner lead 12, and adjacent leads 103 are connected with each other by a dam bar 102.

When the lead frame is applied to packages in the form of DIP (Dual In-line Package), QFP (Quad Flat Package), SOP (Small Out-Line Package), etc., the outer leads 13 need to be exposed and cannot be covered by a molding layer during the process of package. Specifically, when packaging, a semiconductor chip (not shown in the figures) is first mounted on the front surface of the base island 100, followed by the formation of a metal wire (not shown in the figures) connecting the semiconductor chip with the inner lead 12 of the lead 103, and then a molding layer (not shown in the figures) is formed that covers the base island 100, the semiconductor chip, and the inner lead.

When forming the molding layer, upper and lower molds are required, and the dam bar and a part of the leads between the dam bars are pressed together between the upper and lower molds, and the dam bar 102 is configured to prevent the molding layer material from overflowing outwardly to the outer leads 13 during the formation of the molding layer, which would affect the subsequent process of bending the outer leads 13. After forming the molding layer, the removal of the dam bar 102 is required to make the adjacent leads 103 discrete from each other, and electroplating is required at the location where the dam bar 102 is removed to prevent oxidization of the leads, which makes the manufacturing process more complicated, and the manufacturing efficiency is low, and the rib-cutting and electroplating require additional rib-cutting equipment and electroplating equipment, which makes the manufacturing costs higher.

The technical problem to be solved by the present application is to provide a lead frame and a package structure, which improve manufacturing efficiency and save manufacturing costs.

The advantages of the technical solution of the present application include the following.

The lead frame and package structure in the aforementioned embodiment of the present application, wherein the lead frame includes a UV tape covering a back surface and/or a front surface of the connection part of each of the leads and filling the gaps between the connection parts of the adjacent leads, and the UV tape prevents the molding layer material from overflowing in the direction of the outer leads through the gaps between adjacent leads during subsequent formation of a molding layer covering the base island and the inner leads (and semiconductor chips), and the UV tape being peeled off by irradiation with UV light after forming the molding layer. Specifically, on the one hand, when forming the molding layer, since the front surface and back surface of the connection parts of the leads are pressed together between the upper and lower molds, and since the gaps between the connection parts of the adjacent leads are filled with the UV tape, and thus, when injecting the molding material into the mold to form the molding layer to cover the base island and the inner leads (as well as the semiconductor chip), the molding material cannot overflow outwardly from the gaps between the connection parts of the adjacent leads to the position of the outer leads, thereby preventing the overflowing molding material from affecting the subsequent bending process of the outer leads; on the other hand, the UV tape can be easily formed by a film-applying process, and after the molding layer is formed, the adhesiveness of the UV tape disappears or decreases after being irradiated by UV light, and the UV tape can be easily removed by a film-peeling process, so that the UV tape will not affect the subsequent bending process of the outer leads, and the lead frame of the present application, compared to the existing lead frame which also requires cut ribbing and electroplating, its process is simple, it improves the production efficiency and it has lower costs, and because there is no need to invest in additional rib-cutting and electroplating equipment, it saves the space of the package line, and further reduces the costs of the investment line, and the package process does not have the electroplating solution contamination; on yet another hand, the UV tape can also serve for fixing the outer leads during the process of wire bonding and cutting the tie bar of the lead frame, which can prevent the outer leads from moving.

An embodiment of the present application firstly provides a lead frame, with reference to FIGS. 2-5, FIG. 2 is a bottom view structural schematic diagram of the back surface of the lead frame without a UV tape, FIG. 3 is a bottom view structural schematic diagram of the back surface of the lead frame with a UV tape, FIG. 4 is a cross-sectional structural schematic diagram in the direction of the cutting line AB in FIG. 3, and FIG. 5 is a cross-sectional structural schematic diagram in the direction of the cutting line CD in FIG. 3, including: a base island 200; a plurality of leads 203 located around the base island 200, the adjacent leads 203 having between them gaps 206, each of the leads 203 including an inner lead 33 close to the base island 200 and an outer lead 34 far away from the base island 200, the inner lead 33 and the outer lead 34 being connected by a connection part 35 (referring to FIG. 2); and a UV tape 202 covering a back surface and/or a front surface of the connection part 35 of each of the leads 203 and filling the gaps 206 between the connection parts 35 of the adjacent leads, the UV tape 202 being configured to prevent the molding layer material from overflowing in the direction of the outer leads 34 during the subsequent formation of the molding layer covering the base island 200 and the inner leads 33, and after the formation of the molding layer, the UV tape 202 being peeled off by UV light irradiation.

The lead frame is configured to support the packaged semiconductor chip during the package process and to connect the packaged semiconductor chip with the external device.

In one embodiment, the lead frame includes a plurality of lead frame units arranged in rows and columns, each lead frame unit including a base island 200 and a lead area 201 located around the base island 200, the lead area 201 having in it a plurality of discrete leads 203. The structure of only one lead frame unit of the lead frame is illustrated in FIG. 2 and FIG. 3.

The plurality of leads 203 are discrete between adjacent inner leads 33, between adjacent connection parts 35, and between some of the outer leads 34, and adjacent leads 203 having gaps 206 between them. In an embodiment, adjacent lead frame units have between them a tie bar 204, and the end of the outer leads 34 far away from the connection parts 35 of each lead frame unit is connected with the tie bar 204, the base island 200 is connected with the tie bar 204 by dam bar 205. After completion of the package, the tie bar is subsequently removed from the lead frames by cutting, so that the base island 200 and the leads 203 in each lead frame unit are separated from the tie bar to form a plurality of discrete package structures (one lead frame unit corresponds to one package structure).

The base island 200 and lead 203 are separated from each other, and the base island 200 also has a gap with the lead 203. The materials of the base island 200 and the leads 203 are the same, both of which are metals or alloys, and specifically may be copper or copper alloys. In order to reduce the stress and weight of the lead frame, in one embodiment, the lead frame has a second gap 207 in areas other than the lead area 201.

There are two situations in which a plurality of discrete leads are located around the base island. In one embodiment, a plurality of discrete leads 203 are located around the base island 200 (as shown in FIG. 2 or FIG. 3), which subsequently allows the lead frame to be used for package in the form of a QFP (Quad Flat Package). In another embodiment, a plurality of discrete leads 203 are located on two sides of the base island 200, such as on opposed sides of the base island 200, and the lead frames can subsequently be used for packages in the form of DIP (Dual In-line Package), SOP (Small Out-Line Package).

The base island 200 and lead 203 both include opposed front surface 23 and back surface 22, the front surface 23 of the base island 200 being configured to mount a semiconductor chip, the semiconductor chip being electrically connected with the front surface of the inner lead 33 of the lead 203 by means of a metal wire.

The lead frame further comprises a UV (Ultraviolet) tape 202, the UV tape 202 covering the back surface 22 and/or the front surface 23 of the connection part 35 of each of the leads 203 as well as filling the gaps 206 between the connection parts 35 of the adjacent leads. In one embodiment, with reference to FIGS. 3-5, the UV tape 202 covers the back surface 22 of the connection part 35 of each of the leads 203 and fills the gaps 206 between the connection parts 35 of the adjacent leads. In another embodiment, the UV tape 202 covers the front surface 23 of the connection part 35 of each of the leads 203 and fills the gap 206 between the connection parts 35 of the adjacent leads. In another embodiment, the UV tape 202 covers the front surface 23, the back surface 22 of the connection part 35 of each of the leads 203, and fills the gap 206 between the connection parts 35 of the adjacent leads. In the present application, the lead frame includes a UV tape 202 covering a back surface and/or a front surface of the connection part 35 of each of the leads 203 and filling the gap 206 between the connection parts 35 of the adjacent leads, the UV tape 202 can prevent the material of the molding layer 304 from overflowing in the direction of the outer leads 34 through the gaps 206 between adjacent leads 203 during subsequent formation of a molding layer 304 covering the base island 200 and the inner leads 33 (as well as semiconductor chip 301) (referring to FIGS. 6-7); specifically, on the one hand, when forming the molding layer 304, the front surface 23 and the back surface 22 of the connection part 35 of the lead 203 are pressed together between the upper and lower molds, and the gaps 206 between the connection parts 35 of the adjacent leads 203 are filled with the UV tape 202, and thus, when injecting the molding material into the upper and lower molds to form the molding layer 304 covering the base island 200 and the inner leads 33 (as well as the semiconductor chip 301), the molding material cannot overflow outwardly from the gaps 206 between the connection parts 35 of the adjacent leads 203 to the position of the outer leads 34, thereby preventing the overflowing molding material from affecting the subsequent bending process of the outer leads 34; on the other hand, the UV tape 202 can be easily formed by a film-applying process, and after the molding layer 304 is formed, the adhesiveness of the UV tape 202 disappears or decreases after being irradiated by UV light, and the UV tape 202 can be easily removed by a film-peeling process, so that the UV tape 202 will not affect the subsequent bending process of the outer leads. And, the production of the lead frame of the present application does not need rib-cutting or electroplating like the existing lead frame, the process is simple, it improves the production efficiency and has lower costs, and because there is no need to invest in additional rib-cutting and electroplating equipment, it saves the space of the package line, and further reduces the costs of the investment line, and the package process does not involve the electroplating solution contamination; on yet another hand, the UV tape 202 can also serve to fix the leads 203 during the process of wire bonding and cutting the tie bar of the lead frame, which can prevent the leads 203 from moving.

In one embodiment, after forming the molding layer 304, the UV tape 202 can be peeled off after being irradiated by UV light. In another embodiment, after subsequently forming the molding layer 304, the UV tape 202 can be retained.

The UV tape 202 has adhesiveness and ductility, and when irradiated by UV light, the adhesiveness of the UV tape 202 disappears or decreases, and the UV tape 202 can be peeled off by a film-peeling process. The UV tape 202 can be formed by a film-applying process.

In one embodiment, the UV tape 202 includes a base film and an adhesive film located on the surface of the base film, the adhesive film losing or decreasing its adhesiveness under the irradiation of UV light; the adhesive film fills the gap 206 between the connection parts 35 of the adjacent leads 203.

In one embodiment, the UV tape 202 fully fills the gap 206 between the connection parts 35 of the adjacent leads 203 (referring to FIG. 3).

An embodiment of the present application also provides a package structure, with reference to FIG. 6 and FIG. 7 (and in conjunction with reference to FIGS. 2-5), FIG. 6 is a bottom view structural schematic diagram of the back surface of the package structure, and FIG. 7 is a cross-sectional structural schematic diagram in the direction of the cutting line CD in FIG. 6, including: a lead frame, the lead frame including a base island 200 and a plurality of leads 203 located around the base island 200, the adjacent leads 203 having between them a gap 206, each of the leads 203 including an inner lead 33 close to the base island 200 and an outer lead 34 far away from the base island 200, the inner lead 33 and the outer lead 34 being connected by a connection part 35; a semiconductor chip 301 mounted on the front surface 23 of the base island 200, the semiconductor chip 301 being electrically connected with the inner lead 33 by a metal wire 302; a UV tape 202 covering a back surface and/or a front surface of the connection part 35 of each of the leads 203 and filling the gap 206 between the connection parts 35 of the adjacent leads 203, the UV tape 202 being configured for preventing the material of the molding layer 304 (referring to FIG. 6 and FIG. 7) from overflowing in the direction of the outer leads 34 through the gaps 206 between adjacent leads 203 during the formation of a molding layer 304 covering the semiconductor chip 301, the base island 200 and the inner leads 33; and a molding layer 304 covering the semiconductor chip 301, the base island 200 and the inner lead 33, the molding layer 304 exposing the outer lead 34 and the UV tape 202.

In one embodiment, the lead frame includes a plurality of lead frame units arranged in rows and columns, each lead frame unit including a base island 200 and a plurality of discrete leads 203 located around the base island 200, and each lead frame unit having the semiconductor chip 301, the molding layer 304, and the UV tape 202.

In one embodiment, the base island 200 and leads 203 both include opposed front surface and back surface, the semiconductor chip 301 includes opposed active surface and back surface, the active surface having a plurality of discrete pads, the back surface of the semiconductor chip 301 being mounted, with its back surface facing downward, on the front surface of the base island 200, and the pads on the active surface being electrically connected with the corresponding inner leads 33 by means of metal wires 302. In one embodiment, the back surface of the semiconductor chip 301 is mounted on the front surface of the base island 200 by means of an adhesive layer. In one embodiment, the material of the pads is one or more of aluminum, copper, titanium, nickel, tin, tungsten, platinum, chromium, tantalum, gold, or silver, the material of the metal wires 302 is one or more of gold, aluminum, copper, silver, nickel, or palladium, and the process of formation of the metal wires 302 includes a lead bonding process or a wire bonding process (WB).

In one embodiment, the semiconductor chip 301 includes, but is not limited to, a signal processing semiconductor chip, a logic control semiconductor chip, a storage semiconductor chip, a sensor semiconductor chip, a power supply semiconductor chip, or an RF semiconductor chip, according to different functions.

In one embodiment, after forming the molding layer 304, the UV tape 202 can be peeled off after being irradiated by UV light. In another embodiment, after forming the molding layer 304, the UV tape 202 may be retained.

In one embodiment, the UV tape 202 includes a base film and an adhesive film located on the surface of the base film, the adhesive film losing or decreasing its adhesiveness under the irradiation of UV light; the adhesive film is filled in the gap 206 between the connection parts 35 of the adjacent leads 203.

In one embodiment, the front surface and back surface of the connection part 35 are used to press together between the upper and lower molds when forming the molding layer 304.

In one embodiment, referring to FIG. 8, after forming the molding layer 304, the tie bar in the lead frame is cut and removed to form a plurality of discrete package structures, and then the UV tape 202 in each of the package structures is irradiated with UV light to peel off the UV tape 202, and after peeling off the UV tape 202, the outer leads 34 in the leads 203 are bent.

In one embodiment, referring to FIG. 9, after forming the molding layer 304, the tie bar in the lead frame is cut and removed to form a plurality of discrete package structures, and the UV tape 202 is retained; and the outer lead 34 in the lead 203 is bent.

An embodiment of the present application also provides a method for forming a package structure, which is described in detail below in conjunction with the accompanying drawings.

Referring to FIG. 2, a lead frame is provided, the lead frame including a base island 200 and a plurality of leads 203 located around the base island 200, the adjacent leads 203 having between them a gap 206, each of the leads 203 including an inner lead 33 close to the base island 200 and an outer lead 34 far away from the base island 200, the inner lead 33 and the outer lead 34 being connected by a connection part 35.

In one embodiment, the lead frame includes a plurality of lead frame units arranged in rows and columns, each lead frame unit including a base island 200 and a lead area 201 located around the base island 200, the lead area 201 in it having a plurality of discrete leads 203. The structure of one lead frame unit of the lead frame is illustrated in FIG. 2 and FIG. 3.

The plurality of leads 203 are discrete between adjacent inner leads 33, between adjacent connection parts 35, and between portions of outer leads 34, adjacent leads 203 having between them gaps 206. In one embodiment, adjacent lead frame units have between them a tie bar 204, with the end of the outer leads 34 far away from the connection parts 35 of each lead frame unit being connected with the tie bar 204; the base island 200 is connected with the tie bar 204 by dam bar 205. After completion of the package, the tie bars in the lead frames are subsequently removed by cutting, so that the base island 200 and the leads 203 in each lead frame unit are separated from the tie bar to form a plurality of discrete package structures (one lead frame unit corresponds to one package structure).

The base islands 200 and leads 203 are separated from each other, and the base islands 200 and leads 203 also have gaps from each other.

In one embodiment, the lead frames are formed by performing stamleadg, etching, heat treating, and other processes on a coil of incoming material.

In one embodiment, it further includes performing electroplating to form a protective metal layer on the surface of the leads 203.

Referring to FIGS. 3-5, FIG. 4 is a cross-sectional structural schematic diagram in the direction of the cutting line AB in FIG. 3, and FIG. 5 is a cross-sectional structural schematic diagram in the direction of the cutting line CD in FIG. 3, a UV tape 202 is formed to cover a back surface and/or a front surface of the connection part 35 of each of the leads 203 as well as to fill in the gaps between the connection parts 35 of the adjacent leads 203.

The UV tape 202 is configured for preventing the material of the molding layer 304 from overflowing in the direction of the outer leads 34 through the gaps 206 between adjacent leads 203 during the formation of a molding layer 304 (referring to FIG. 6 and FIG. 7) covering the semiconductor chip 301, the base island 200 and the inner leads 33.

In one embodiment, subsequently after forming the molding layer 304, the UV tape is retained, or subsequently after forming the molding layer 304, the UV tape 202 is peeled off by UV light irradiation.

In one embodiment, subsequently after forming the molding layer 304, the UV tape 202 can be peeled off after being irradiated by UV light. In another embodiment, subsequently after forming the molding layer 304, the UV tape 202 can be retained.

The UV tape 202 has adhesiveness and ductility, and when irradiated by UV light, the adhesiveness of the UV tape 202 disappears or decreases, and the UV tape 202 can be peeled off by a film-peeling process. The UV tape 202 can be formed by a film-applying process.

In one embodiment, the UV tape 202 includes a base film and an adhesive film located on the surface of the base film, the adhesive film losing or decreasing its adhesiveness under the irradiation of UV light; the adhesive film is filled in the gap 206 between the connection parts 35 of the adjacent leads 203.

Referring to FIG. 6 and FIG. 7, a semiconductor chip 301 is mounted on the front surface of the base island 200; a metal wire 302 is formed that electrically connects the semiconductor chip 301 with the inner lead 33; a molding layer 304 is formed to cover the semiconductor chip 301, the base island 200, and the inner lead 33, and the molding layer 304 exposes the outer lead 34 and the UV tape 202, the UV tape 202 is configured to prevent the material of the molding layer 304 overflowing in the direction of the outer lead 34 through the gaps 206 between the adjacent leads 203 when forming the molding layer 304 covering the semiconductor chip 301, the base island 200 and the inner lead 33.

In one embodiment, the base island 200 and lead 203 both include opposed front surface and back surface, the semiconductor chip 301 includes opposed active surface and back surface, the active surface having a plurality of discrete pads, the semiconductor chip 301 is mounted, with its back surface facing downward, on the front surface of the base island 200, and the pads on the active surface are electrically connected with the corresponding inner leads 33 by means of metal wires 302. In one embodiment, the back surface of the semiconductor chip 301 is mounted on the front surface of the base island 200 by means of an adhesive layer. In one embodiment, the material of the pads is one or more of aluminum, copper, titanium, nickel, tin, tungsten, platinum, chromium, tantalum, gold, and silver, the material of the metal wires 302 is one or more of gold, aluminum, copper, silver, nickel, and palladium, and the process for forming the metal wires 302 includes a lead bonding process or a wire bond process (WB).

An injection molding process is used to form the molding layer 304, and when the injection molding process is carried out, the front surface and back surface of the connection part 35 of the lead 203 are pressed together between the upper and lower molds, and the base island 200, semiconductor chip 301, and metal wire 302 are located inside the upper and lower molds, and the outer lead 34 is located outside the upper and lower molds, and a molding material is injected inside the upper and lower molds to form a molding layer 304 to cover the semiconductor chip 301, the base island 200 and the inner lead 33, and the molding layer 304 exposes the outer lead 34 and the UV tape 202.

In one embodiment, referring to FIG. 7 and FIG. 8, after forming the molding layer 304, the UV tape 202 is peeled off after the UV tape is irradiated with UV light; the outer lead 34 of the lead 203 is bent.

In another embodiment, after forming the molding layer 304, the UV tape 202 is retained; the outer lead 34 of the lead 203 is bent, and the UV tape 202 is able to fix the outer lead 34 during the process of bending the outer lead 34 of the lead 203, which ensures the precision of the position of the bent outer lead 34.

Although the present application has been disclosed as above with preferred embodiments, it is not intended to limit the present application, and any person skilled in the art may, without departing from the spirit and scope of the present application, make possible changes and modifications to the technical solutions of the present application by utilizing the above disclosed methods and technical contents, therefore, any simple modifications, equivalent changes, and modifications made to the above embodiments based on the technical substance of the present application without departing from the content of the technical solutions of the present application are within the scope of protection of the technical solutions of the present application.

What is claimed is:

1. A lead frame, comprising:
a base island;
a plurality of leads located around the base island, the adjacent leads having between them a gap, each of the lead comprising an inner lead close to the base island and an outer lead far away from the base island, the inner lead and the outer lead being connected by a connection part; and
an ultraviolet (UV) tape covering at least one of a back surface or a front surface of the connection part of each of the leads and filling the gaps between the connection parts of the adjacent leads, the UV tape being configured to prevent molding layer material from overflowing in a direction of the outer leads through the gaps between the adjacent leads during subsequent formation of a molding layer covering the base island and the inner leads.

2. The lead frame according to claim 1, wherein
the UV tape is retained after formation of the molding layer or the UV tape is removed after formation of the molding layer by irradiation with UV light;
the UV tape comprises a base film and an adhesive film located on a surface of the base film, the adhesive film losing or diminishing its adhesiveness under the irradiation of UV light; and
the adhesive film is filled in the gaps between the connection parts of the adjacent leads.

3. The lead frame according to claim 1, wherein the UV tape fully fills the gaps between the connection parts of the adjacent leads.

4. The lead frame according to claim 1, further comprising a plurality of lead frame units arranged in rows and columns, each lead frame unit comprising a base island and a plurality of discrete leads located around the base island.

5. The lead frame according to claim 4, wherein adjacent lead frame units have between them a tie bar, an end of the outer lead in each lead frame unit far away from the connection part being connected with the tie bar, and the base island being connected with the tie bar by means of a dam bar.

6. The lead frame according to claim 4, wherein a plurality of discrete leads being located around the base island comprises the plurality of discrete leads being located around the base island, or the plurality of discrete leads being located on two sides of the base island.

7. A package structure, comprising:
a lead frame, the lead frame comprising a base island and a plurality of leads located around the base island, the adjacent leads having between them a gap, each of the leads comprising an inner lead close to the base island and an outer lead far away from the base island, the inner lead and the outer lead being connected by a connection part;
a semiconductor chip mounted on a front surface of the base island, the semiconductor chip being electrically connected with the inner leads by means of metal wires;
a molding layer covering the semiconductor chip, the base island, and the inner leads, the molding layer exposing the outer leads;
an ultraviolet (UV) tape covering at least one of a back surface or a front surface of the connection part of each of the leads and filling the gap between the connection parts of the adjacent leads; and
a molding layer covering the semiconductor chip, the base island, and the inner leads, the molding layer exposing the outer leads and the UV tape.

8. The package structure according to claim 7, wherein a plurality of the leads are located around the base island or a plurality of the leads are located on two sides of the base island.

9. The package structure according to claim 7, wherein
the UV tape is retained after formation of the molding layer or the UV tape is removed after formation of the molding layer by irradiation with UV light;
the UV tape comprises a base film and an adhesive film located on a surface of the base film, the adhesive film losing or diminishing its adhesiveness under the irradiation of UV light; and
the adhesive film is filled in the gaps between the connection parts of the adjacent leads.

10. The package structure according to claim 7, wherein the UV tape fully fills the gaps between the connection parts of the adjacent leads.

11. The package structure according to claim 7, further comprising a plurality of lead frame units arranged in rows and columns, each lead frame unit comprising a base island and a plurality of discrete leads located around the base island.

12. The package structure according to claim 11, wherein adjacent lead frame units have between them a tie bar, an end of the outer lead in each lead frame unit far away from the connection part being connected with the tie bar, and the base island being connected with the tie bar by means of a dam bar.

13. The package structure according to claim 11, wherein a plurality of discrete leads being located around the base island comprises the plurality of discrete leads being located around the base island, or the plurality of discrete leads being located on two sides of the base island.

14. A method for forming a package structure, comprising:
providing a lead frame, the lead frame comprising a base island and a plurality of leads located around the base island, the adjacent leads having between them a gap, each of the leads comprising an inner lead close to the base island and an outer lead far away from the base island and connected with the inner lead, the inner lead and the outer lead being connected by a connection part;
forming an ultraviolet (UV) tape which covers at least one of a back surface or a front surface of the connection part of each of the leads and which fills the gap between the connection parts of the adjacent leads;
mounting a semiconductor chip on the front surface of the base island;
forming a metal wire electrically connecting the semiconductor chip with the inner leads; and
forming a molding layer that covers the semiconductor chip, the base island and the inner leads, the molding layer exposing the outer leads and the UV tape, the UV tape being configured to prevent molding layer material from overflowing in a direction of the outer leads through the gaps between the adjacent leads during subsequent formation of a molding layer covering the semiconductor chip, the base island and the inner leads.

15. The method for forming a package structure according to claim 14, wherein the UV tape is retained after forming the molding layer, or the UV tape is removed by UV light irradiation after forming the molding layer.

16. The method for forming a package structure according to claim 14, wherein the base island and leads both comprise opposed front surface and back surface, and the semiconductor chip comprises opposed active surface and back surface, the active surface having a plurality of discrete pads, the semiconductor chip being mounted, with its back surface facing downwards, on the front surface of the base island, and the pads on the active surface of the semiconductor chip being electrically connected with the corresponding inner leads.

17. The method for forming a package structure according to claim 16, wherein when forming the molding layer, the front surface and back surface of the connection part are pressed together between the upper and lower molds.

18. The method for forming package structure according to claim 14, wherein
the UV tape comprises a base film and an adhesive film located on a surface of the base film, the adhesive film losing or diminishing its adhesiveness under irradiation of UV light; and
the adhesive film is filled in the gaps between the connection parts of the adjacent leads.

19. The method for forming package structure according to claim 14, wherein the UV tape fully fills the gaps between the connection parts of the adjacent leads.

20. The method for forming package structure according to claim 14, wherein providing a lead frame comprises providing a plurality of lead frame units arranged in rows and columns, each lead frame unit comprising a base island and a plurality of discrete leads located around the base island.
